(19) United States
(12) Patent Application Publication
(10) Pub. No.: US 2026/0231421 A1
(43) Pub. Date: Aug. 6, 2026

(54) SPLIT PILLAR MEMORY ARCHITECTURES

(71) Applicant: Micron Technology, Inc., Boise, ID (US)

(72) Inventors: Lorenzo Fratin, Buccinasco (IT); Paolo Fantini, Vimercate (MB) (IT); Enrico Varesi, Milano (MI) (IT); Zhao Zhao, Meridian, ID (US)

(21) Appl. No.: 19/450,584

(22) Filed: Jan. 15, 2026

Related U.S. Application Data
(60) Provisional application No. 63/753,210, filed on Feb. 3, 2025.

(51) Int. Cl. H10B 43/35; G11C 5/06; G11C 16/04; H10B 41/10; H10B 41/27; H10B 41/35; H10B 43/10; H10B 43/27; H10D 30/01; H10D 30/68; H10D 30/69; H10D 62/17

(52) U.S. Cl. CPC H10B 43/35; G11C 5/063; G11C 16/0483; H10B 43/10; H10B 43/27; H10D 30/0413; H10D 30/693; H10D 62/292; H10B 41/10; H10B 41/27; H10B 41/35; H10D 30/0411; H10D 30/689

(57) ABSTRACT

Methods, systems, and devices for split pillar memory architectures are described. A memory device may include a first pillar including a first dielectric material, a second pillar including the first dielectric material, and a third pillar positioned between the first pillar and the second pillar and including a second dielectric material. The memory device may also include a first portion of a first semiconductor material along a first side of the third pillar and a second portion of the first semiconductor material along a second side of the third pillar opposite the first side. The memory device may further include a first portion of a second semiconductor material positioned between multiple word lines and the first portion of the first semiconductor material and include a second portion of the second semiconductor material positioned between the multiple word lines and the second portion of the first semiconductor material.

### CROSS REFERENCE

The present Application for Patent claims priority to U.S. patent application Ser. No. 63/753,210 by Fratin et al., entitled “SPLIT PILLAR MEMORY ARCHITECTURES,” filed Feb. 3, 2025, which is assigned to the assignee hereof, and which is expressly incorporated by reference in its entirety herein.

### TECHNICAL FIELD

The following relates to one or more systems for memory, including split pillar memory architectures.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a memory system that supports split pillar memory architectures in accordance with examples as disclosed herein.

FIG. 2 shows an example of a memory architecture that supports split pillar memory architectures in accordance with examples as disclosed herein.

FIGS. 3A and 3B show an example of a memory device that supports split pillar memory architectures in accordance with examples as disclosed herein.

FIGS. 4A through 4K show an example of a method to manufacture split pillar memory architectures in accordance with examples as disclosed herein.

FIG. 5 shows a flowchart illustrating a method or methods that support split pillar memory architectures in accordance with examples as disclosed herein.

### DETAILED DESCRIPTION

Some memory devices, not AND (NAND) memory devices, may include three dimensional (3D) architectures. For example, a memory device may include multiple pillars, where each pillar of the multiple pillars may include multiple memory cells (formed along the z direction). In some cases, however, such devices may be limited in scale. For example, a density of a 3D memory device architecture, among other features, may be limited during manufacturing, thereby reducing a quantity of memory cells formed (e.g., integrated) in each device. Additionally, in some cases, the manufacturing of such memory devices may incur increased costs relative to other memory devices. Thus, techniques may be desired to increase a density of 3D memory devices, without incurring additional costs, without incurring additional manufacturing times, and without reducing the sustainability (e.g., lifetime or quality) of the memory cells.

According to the techniques described herein, to increase the scalability of memory devices, a memory device may be formed that includes multiple pillars, including a first dielectric pillar and a second dielectric pillar. The memory device may also be formed to include a third pillar (e.g., a pier, an active pillar, a pillar associated with memory cells) positioned between the first and second pillars, such that the first pillar may be in contact with a first side of the third pillar (along the x-direction) and the second pillar may be in contact with a second side of the third pillar opposite the first side. In this way, the first dielectric pillar and the second dielectric pillar may isolate the third pillar from other active pillars of the memory device.

The memory device may be formed to include a first portion of a first semiconductor material along a third side of the third pillar (along the y-direction) and include a second portion of the first semiconductor material along a fourth side of third pillar opposite the third side. The memory device may also include a first portion of a second semiconductor material positioned between multiple word lines and the first portion of the first semiconductor material and include a second portion of the second semiconductor material positioned between the multiple word lines and the second portion of the first semiconductor material.

Each portion of the second semiconductor material may form multiple memory cells, such that multiple first memory cells (along the z direction) may be formed at the third end of the third pillar and multiple second memory cells (along the z direction) may be formed at the fourth end of the third pillar. In such examples, the first portion of the first semiconductor material may form a first bit line configurable to bias the multiple first memory cells, and the second portion of the first semiconductor material may be a second bit line configurable to bias the multiple second memory cells.

In this way, by forming a pillar to have first and second portions of the second semiconductor material, the memory device may include (e.g., integrate) an increased quantity of memory cells per pillar (e.g., double the memory cells) relative to other memory devices (e.g., a single pillar with a single set of multiple memory cells). Further, in such examples, to maintain a quality (e.g., lifespan) of the memory cells, the portions of the second semiconductor material may be formed with a hemicylindrical form, which may increase the strength of the electrical field at the center of each memory cell along the portions of the first semiconductor material, thereby maintaining, or improving, the sustainability of the memory cells.

In addition to applicability in memory systems as described herein, techniques for split pillar memory architectures may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by splitting the second semiconductor material (e.g., NAND channel material, memory cell material) into a first and second portions along an active pillar, the quantit of memory cells within a memory device may be increased, which may reduce electronic waste, extend the life of electronic devices and thereby reducing electronic waste, among other benefits.

Features of the disclosure are illustrated and described in the context of systems, devices, and circuits. Features of the disclosure are further illustrated and described in the context of memory devices, methods of manufacturing, and flowcharts.

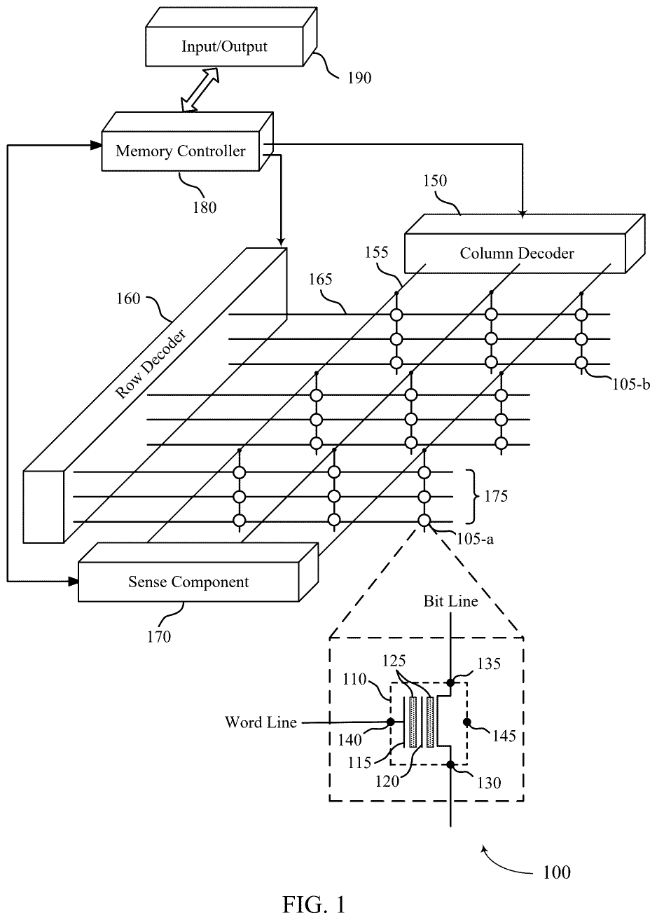

FIG. 1 shows an example of a memory system 100 that supports split pillar memory architectures in accordance with examples as disclosed herein. FIG. 1 is an illustrative representation of various components and features of the memory system 100. As such, the components and features of the memory system 100 are shown to illustrate functional interrelationships, and not necessarily physical positions within the memory system 100. Further, although some elements included in FIG. 1 are labeled with a numeric indicator, some other corresponding elements are not labeled, even though they are the same or would be understood to be similar, in an effort to increase visibility and clarity of the depicted features.

The memory system 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

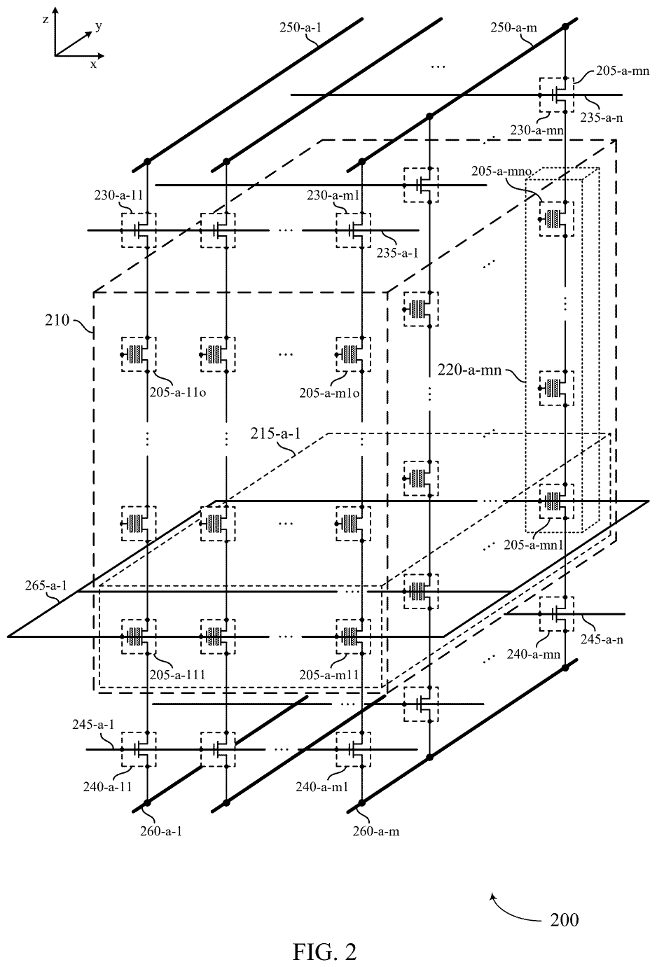

In some cases, a memory system 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory system 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory system 100.

According to the techniques described herein, to increase the scalability of memory devices (e.g., 3D-NAND memory devices of the memory system 100), a memory device may be formed that includes multiple pillars, including a first dielectric pillar and a second dielectric pillar. The memory device may also be formed to include a third pillar (e.g., a pier, an active pillar, a pillar associated with memory cells) positioned between the first and second pillars, such that the first pillar may be in contact with a first side of the third pillar (along the x-direction) and the second pillar may be in contact with a second side of the third pillar opposite the first side. In this way, the first dielectric pillar and the second dielectric pillar may isolate the third pillar from other active pillars of the memory device.

The memory device may be formed to include a first portion of a first semiconductor material along a third side of the third pillar (along the y-direction) and include a second portion of the first semiconductor material along a fourth side of third pillar opposite the third side. The memory device may also include a first portion of a second semiconductor material positioned between multiple word lines 165 and the first portion of the first semiconductor material and include a second portion of the second semiconductor material positioned between the multiple word lines 165 and the second portion of the first semiconductor material.

Each portion of the second semiconductor material may form multiple memory cells 105, such that multiple first memory cells 105 (along the z direction) may be formed at the third end of the third pillar and multiple second memory cells 105 (along the z direction) may be formed at the fourth end of the third pillar. In such examples, the first portion of the first semiconductor material may form a first bit line 155 configurable to bias the multiple first memory cells 105, and the second portion of the first semiconductor material may be a second bit line 155 configurable to bias the multiple second memory cells 105.

FIG. 2 shows an example of a memory architecture 200 that supports split pillar memory architectures in accordance with examples as disclosed herein. The memory architecture 200 may be an example of a portion of a memory system, such as a memory system 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110, NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory system 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with the same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0value) and read from in accordance with a granularity, such as at the granularity of a page 215 or portion thereof, but may not be erasable (e.g., reset to a logic 1 value) in accordance with the granularity, such as the granularity of a page 215 or portion thereof. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget>VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

According to the techniques described herein, to increase the scalability of memory devices (e.g., 3D-NAND memory devices of the memory system 100 and the memory architecture 200), a memory device may be formed that includes multiple pillars, including a first dielectric pillar and a second dielectric pillar. The memory device may also be formed to include a third pillar (e.g., a pier, an active pillar, a pillar associated with memory cells) positioned between the first and second pillars, such that the first pillar may be in contact with a first side of the third pillar (along the x-direction) and the second pillar may be in contact with a second side of the third pillar opposite the first side. In this way, the first dielectric pillar and the second dielectric pillar may isolate the third pillar from other active pillars of the memory device.

The memory device may be formed to include a first portion of a first semiconductor material along a third side of the third pillar (along the y-direction) and include a second portion of the first semiconductor material along a fourth side of third pillar opposite the third side. The memory device may also include a first portion of a second semiconductor material positioned between multiple word lines 265 and the first portion of the first semiconductor material and include a second portion of the second semiconductor material positioned between the multiple word lines 265 and the second portion of the first semiconductor material.

Each portion of the second semiconductor material may form multiple memory cells 205, such that multiple first memory cells 205 (along the z direction) may be formed at the third end of the third pillar and multiple second memory cells 205 (along the z direction) may be formed at the fourth end of the third pillar. In such examples, the first portion of the first semiconductor material may form a first bit line 250 configurable to bias the multiple first memory cells 205, and the second portion of the first semiconductor material may be a second bit line 250 configurable to bias the multiple second memory cells 205.

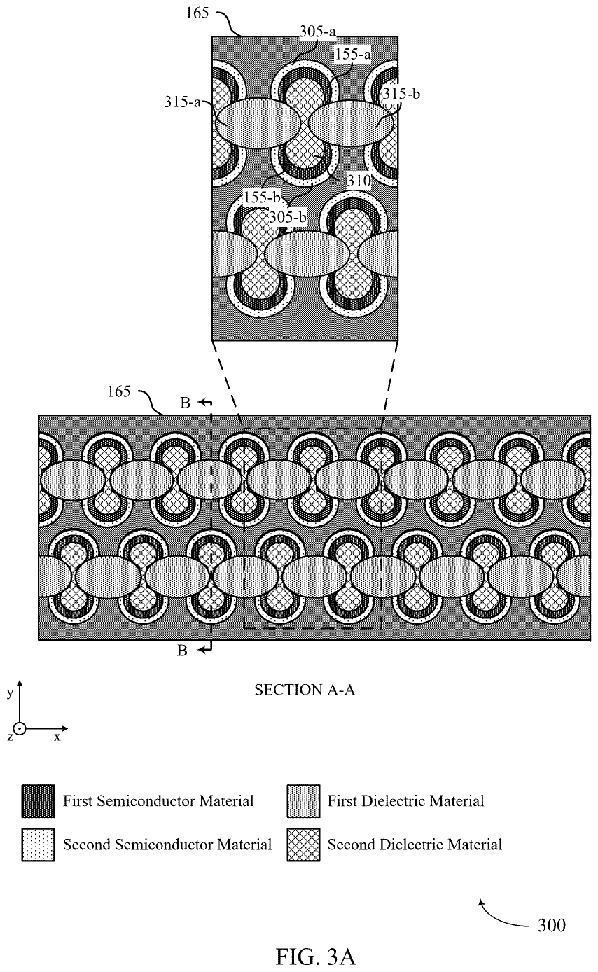

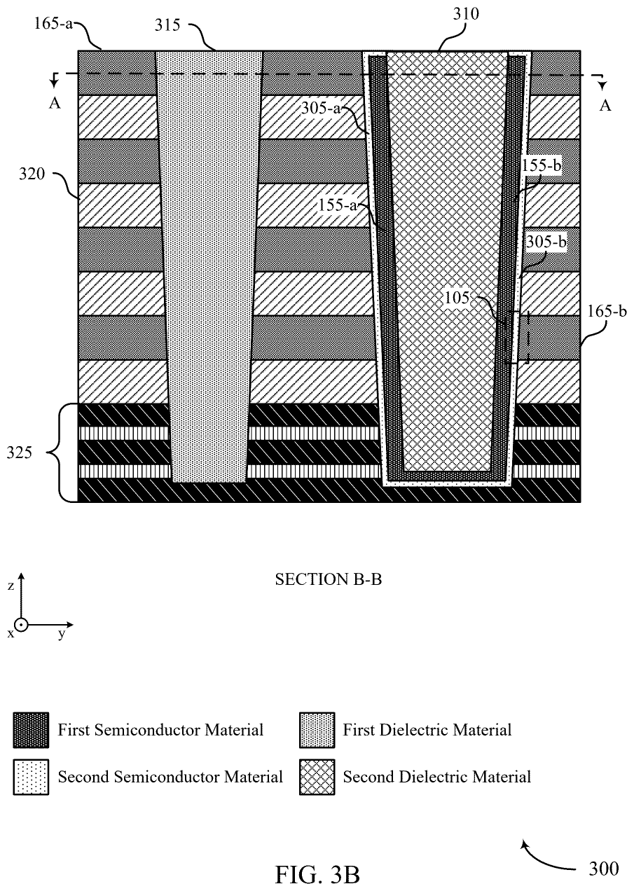

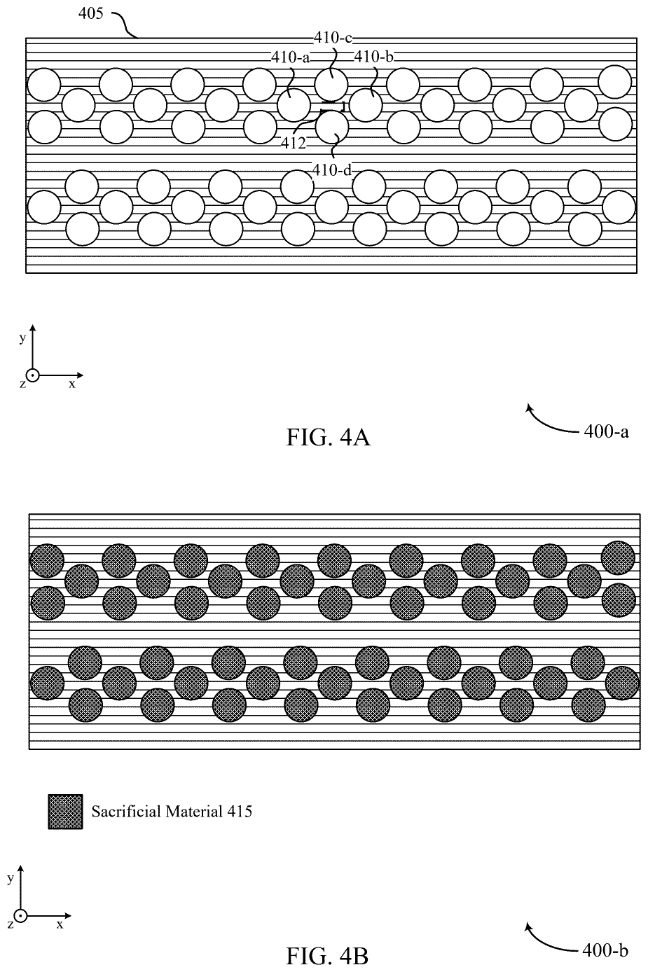

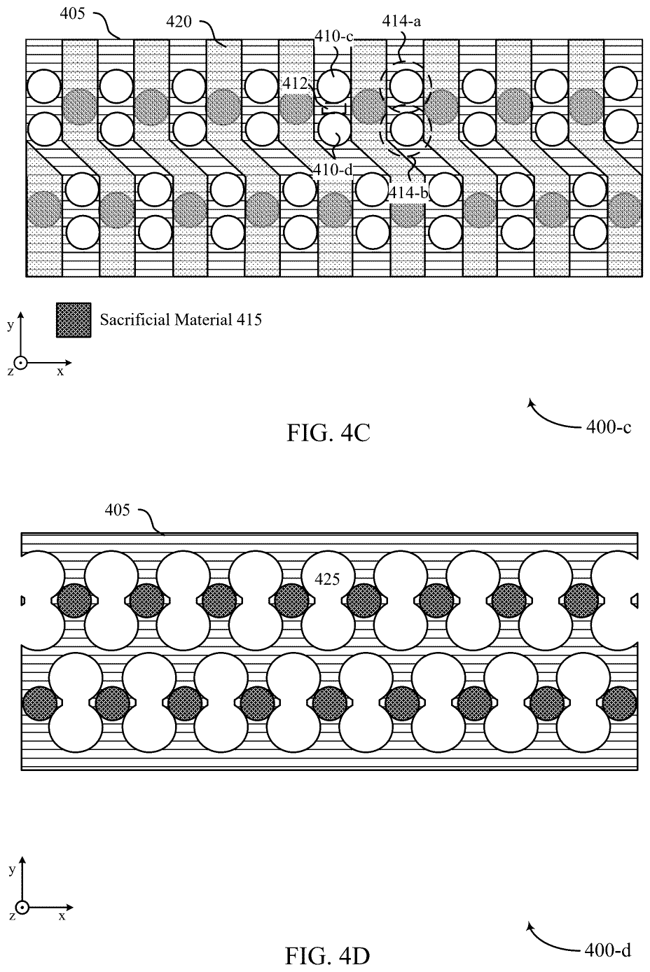

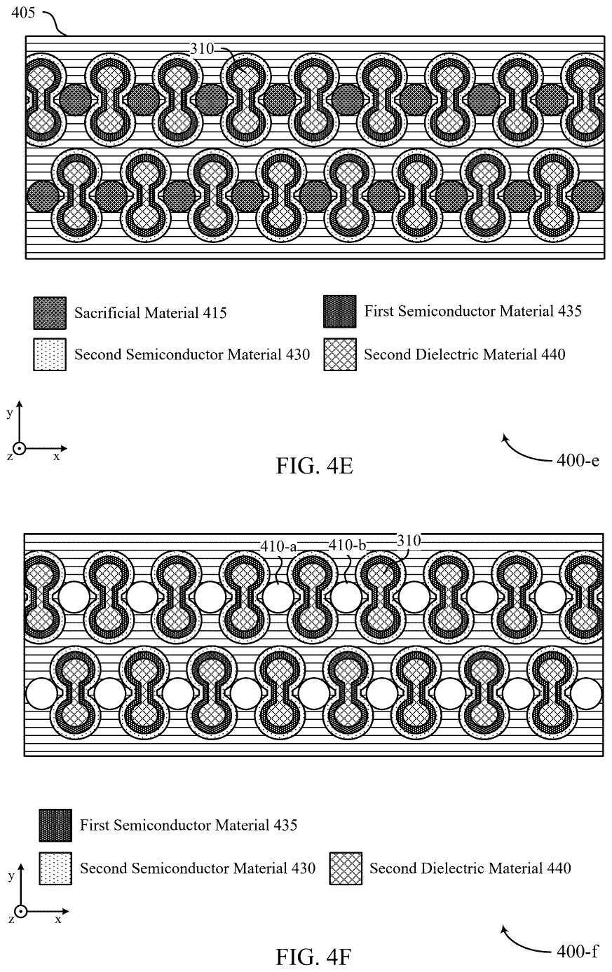

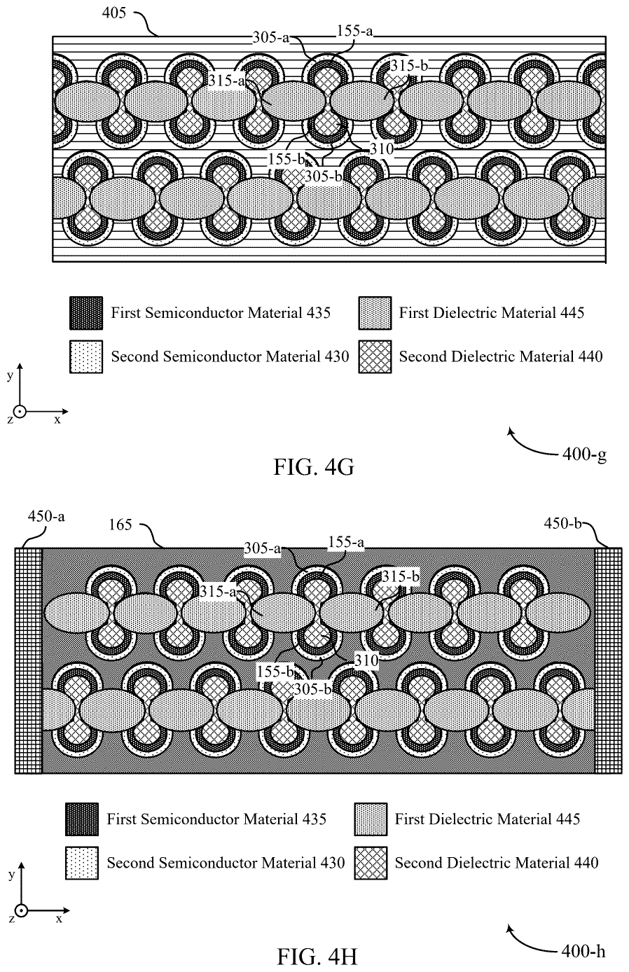

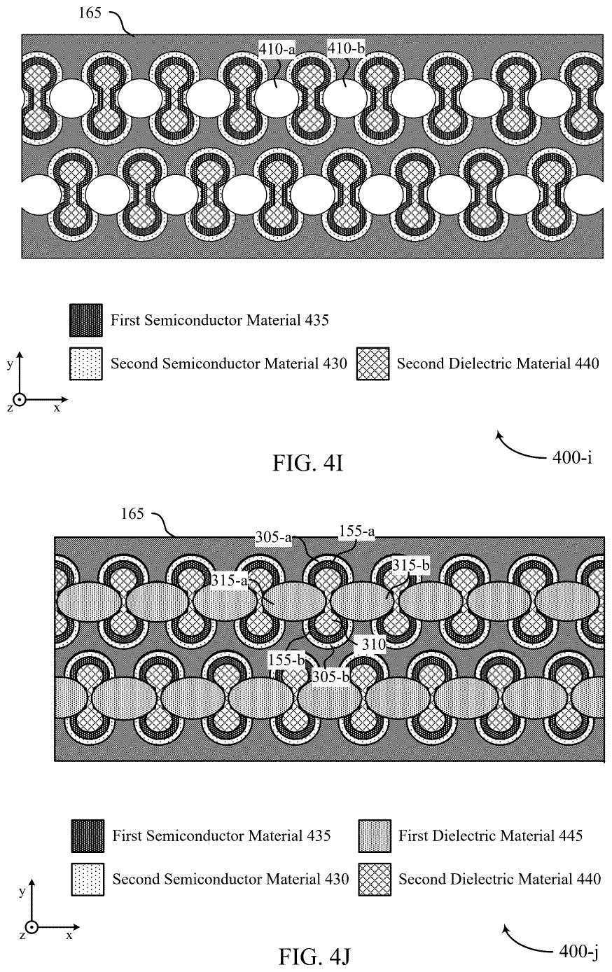

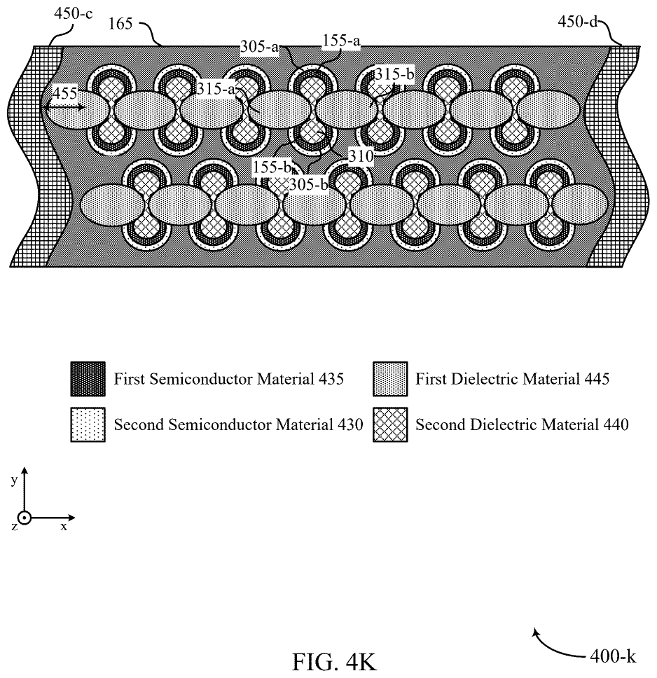

FIGS. 3A and 3B show an example of a memory device 300 that supports split pillar memory architectures in accordance with examples as disclosed herein. Aspects of the memory device 300 may be implemented by the memory system 100 and the memory architecture 200 as described herein. For example, the memory device 300 may be an example of a memory device implemented in the memory system 100 as described herein with reference to FIG. 1. The memory device 300 may be formed according to techniques further described herein with reference to FIGS. 4A through 4J and may be formed to include an increased quantity of memory cells (relative to memory cells including a single pillar with a single set of memory cells), while also maintaining the sustainability and quality of the memory cells.

For example, the memory device 300 may include multiple pillars 310 (e.g., active pillars, pillars associated with a memory cell, piers) positioned between a respective pair of dielectric pillars 315. In such examples, the pillars 310 may include a first dielectric material and the dielectric pillars 315 may include a second dielectric material (e.g., oxide), where the first and second dielectric materials may be the same or different. As illustrated in the cross-sectional view A-A, a pillar 310 may be positioned between a dielectric pillar 315-a and a dielectric pillar 315-b. In such examples, the dielectric pillar 315-a may be in contact (e.g., coupled) with a first side of the pillar 310 along the x-direction and the dielectric pillar 315-b may be in contact (e.g., coupled) with a second side of the pillar 310 opposite the first side. Such dielectric pillars 315 may isolate each pillar 310 of the memory device from another pillar 310 and also provide structural support for each pillar 310.

Each pillar 310 may be in contact (e.g., coupled) with portions of a first semiconductor material (e.g., doped polysilicon). For example, a pillar 310 may be in contact with a first portion of the first semiconductor material at a third side of the pillar 310 (along the y-direction) and be in contact with a second portion of the first semiconductor material at a fourth side of the pillar 310 opposite the third side. In such examples, the first portion of the first semiconductor material may form a bit line 155-a, and the second portion of the first semiconductor material may form a bit line 155-b.

The memory device 300 may also include portions 305 of a second semiconductor material (e.g., a cell stack, a NAND channel). For example, a portion 305-a (e.g., first portion) of the second semiconductor material may be in contact with an outer edge of the bit line 155-a at the third side of the pillar, and the portion 305-b (e.g., second portion) of the second semiconductor material may be in contact with an outer edge of the bit line 155-b at the fourth side of the pillar. As illustrated in the cross-sectional view A-A, the dielectric pillars 315 may isolate the portion 305-a from the portion 305-b and isolate the bit line 155-a from the bit line 155-b.

The portions 305 and the bit lines 155 may be formed to continuously extend along a length of the pillar 310. For example, as illustrated in the cross-sectional view B-B, the bit lines 155 may extend along the length of the pillar 310 along the z-direction. Similarly, the portions 305 may also extend along a length of the pillar 310 along the z-direction. The portions 305 may each form multiple memory cells 105. For example, the portion 305-a may form (or be associated with) multiple first memory cells, and the portion 305-b may form (or be associated with) multiple second memory cells. As illustrated in the cross-sectional view B-B, each pillar 310 of the multiple pillars 310 may be associated with a first set of memory cells 105 at the third side of the pillar 310 and be associated with a second set of memory cells 105 at the fourth side of the pillar 310.

The memory device 300 may also include multiple word lines 165, where each word line 165 of the multiple word lines 165 may be located at a respective level of the memory device 300 along the z-direction and be separated by a respective oxide layer 320. In such examples, each word line 165 may couple with a respective memory cell 105 of the portions 305. For example, with respect to the cross-sectional view B-B, the word line 165-a may be coupled with a first memory cell 105 of the portion 305-a and a first memory cell 105 of the portion 305-b. Similarly, a word line 165-b may be coupled with a second memory cell 105 of the portion 305-a and a second memory cell 105 of the portion 305-b. To access a memory cell 105 at a first level of the portion 305-b, a bit line driver may apply a voltage to the bit line 155-b and a word line driver may apply a voltage to a word line 165-b, as described herein with reference to FIGS. 1 and 2.

By forming each pillar 310 to be associated with a portion 305-a and a portion 305-b, the memory device 300 may have a greater quantity of memory cells 105 relative to other memory devices 300 having a single pillar with a single set of memory cells 105 along the pillar. That is, by forming the pillars 310 to have a split pillar structure, the memory device 300 may have an increased array density.

In some examples, to maintain a quality of the memory cells 105 along each portion 305, the portions 305 and bit lines 155 may have one of a hemicylindrical form, a semielliptical form, a rounded rectangular form, or a combination thereof, which may increase the strength of the electrical field at the center of each memory cell 105 along the portions 305, thereby maintaining, or improving, the sustainability of the memory cells 105. For example, the curvature form of the portions 305 may reduce memory cell 105 to memory cell 105 interference due to the electric field lines being contained within the memory cell 105, thereby reducing the likelihood of such electric fields affecting neighboring memory cells 105. Additionally, the curvature form of the portions 305 may improve the endurance of the memory cells 105. That is, because the electric field of each cell may be more evenly distributed across the memory cell 105, the stress on any one point of the memory cell 105 may be reduced, thus increasing the lifespan of the memory cell 105.

FIGS. 4A through 4K show examples of fabrication operations that support split pillar memory architectures in accordance with examples as disclosed herein. For example, FIGS. 4A through 4J may illustrate a sequence of operations for fabricating aspects of an architecture 400 (e.g., as a portion of a semiconductor wafer), which may implement aspects of a memory system 100, a memory architecture 200, a memory device 300, or another implementation of a semiconductor component (e.g., a memory component). In some examples, the architecture 400 may be a portion of memory die, or a wafer that includes multiple memory dies, such as NAND die (e.g., a 3D-NAND die, a die having an arrangement of NAND memory cells in a three-dimensional array). Although some elements included in FIGS. 4A through 4J are labeled with reference numbers, some other corresponding elements are not labeled, though they would be understood by a person having ordinary skill in the art to be the same as or similar to the labeled elements.

Each of FIGS. 4A through 4J may illustrate aspects of the architecture 400 after different subsets of the fabrication operations for forming the architecture 400 (e.g., illustrated as an architecture 400-a after a first set of one or more fabrication operations, as an architecture 400-b after a second set of one or more fabrication operations, and so on). Each view of FIGS. 4A through 4J may be described with reference to an x-direction (e.g., a first direction over a substrate 325, as illustrated in FIG. 3B), a y-direction (e.g., a second direction over the substrate), and a z-direction (e.g., a direction from the substrate) of the illustrated coordinate system, which may correspond to the respective directions described with reference to the memory device 300.

FIG. 4A shows the architecture 400 (e.g., as an architecture 400-a) after a first set of one or more fabrication operations. The techniques described in the context of FIG. 4A may be used to form cavities 410 of the architecture 400. For example, a stack may be deposited over a substrate (e.g., the substrate 325), where the stack may include alternating nitride layers 405 and oxide layers 320 (not shown). After forming the stack, multiple cavities 410 may be formed through the stack along the z-direction. For example, an etching procedure may be performed, such as a wet etching, dry etching, or a combination of both, to form cavities 410. That is, each cavity 410 may be formed at a same time and during a same etching procedure. In some other examples, the cavities 410-a and 410-b may be formed at a first time during a first etching procedure, and the cavities 410-c and 410-d may be formed at a second time during a second etching procedure. Each cavity 410 may extend, along the z-direction, to the substrate or into the substrate, where each cavity 410 may have a tapered profile, as illustrated in FIG. 3B (e.g., a width at the top of the cavities 410 is greater than a width at the bottom of the cavities 410).

The cavities 410-a and 410-b may correspond to a position of the dielectric pillars 315, as described and illustrated in FIG. 3A, and the cavities 410-c and 410-d may correspond to a position of the pillars 310. As illustrated, the cavities 410-c and 410-d may be positioned between the cavity 410-a and the cavity 410-b, and the cavity 410-c may be positioned above, along the positive y-direction, of the cavity 410-d. In some examples, the cavities 410-c and 410-d may be formed, such that a portion 412 of material (e.g., a gap of material) may be maintained between the cavities 410-c and 410-d, where the length of the gap along the y-direction may be determined prior to formation of the cavities 410.

FIG. 4B shows the architecture 400 (e.g., as an architecture 400-b) after a second set of one or more fabrication operations. The techniques described in the context of FIG. 4B may be used to form sacrificial material 415 into each of the cavities 410 of the architecture 400. That is, portions of the sacrificial material 415 may be deposited into each cavity 410. In such examples, the sacrificial material 415 may be Silicon Carbon Nitride (SiCN), doped or undoped poly Silicon, Carbon, hafnium oxide (HfOx), aluminum oxide (AlOx), Carbon Nitride (CN) or a multi-layer combination of such materials.

FIG. 4C shows the architecture 400 (e.g., as an architecture 400-c) after a third set of one or more fabrication operations. The techniques described in the context of FIG. 4C may be used to reform the cavities 410-c and 410-d of the architecture 400. For example, in response to forming the sacrificial material 415 into the cavities 410, a mask 420 may be formed over the portions of the sacrificial material 415 that correspond (positionally) to the cavities 410-a and 410-b. That is, a mask 420 may be formed over a first subset of the portions of the sacrificial material 415, where the first subset corresponds to the cavities 410-a and 410-b. Accordingly, a second subset of the portions of the sacrificial material 415 may be exposed. In response to forming the mask 420, the sacrificial material 415 may be exhumed from the second subset, thereby reforming the cavities 410-c and 410-d.

FIG. 4D shows the architecture 400 (e.g., as an architecture 400-d) after a fourth set of one or more fabrication operations. The techniques described in the context of FIG. 4D may be used to form the cavities 425 of the architecture 400. For example, in response to reforming the cavities 410-c and 410-d, the mask 420 may be removed. After removing the mask, the cavities 425 may be formed. To form the cavities 425, the cavity 410-c and the cavity 410-b may be enlarged, for example, using a selective etch (e.g., wet etch). For example, the nitride material and oxide material 414-a surrounding the cavity 410-c and the nitride material and oxide material 414-b surrounding the cavity 410-d may be selectively etched, thereby enlarging the cavities 410-c and 410-d. As a result of the selective etch, the portion 412 of material separating the cavities 410-c and 410-d may be removed, thereby forming the cavities 425. As such, the cavities 425 may be a combination (e.g., the merging) of the cavity 410-c and the cavity 410-b.

FIG. 4E shows the architecture 400 (e.g., as an architecture 400-e) after a fifth set of one or more fabrication operations. The techniques described in the context of FIG. 4E may be used to form a pillar 310 (e.g., third pillar, pier, active pillar) of the architecture 400.

In some examples, in response to forming to the cavities 425, the second semiconductor material 430 may be formed (e.g., deposited) in the cavities 425. After, a first cavity may be formed through the second semiconductor material 430, where, in response, the first semiconductor material 435 may be formed into the first cavity. After, a second cavity may be formed through the first semiconductor material 435. Accordingly, the second dielectric material 440 may be formed in the second cavity, thereby forming the pillar 310.

In some other examples, in response to forming the cavities 425, the second semiconductor material 430 may be formed along a sidewall of the cavities 425, where the second semiconductor material 430 may have a first thickness. In such examples, if the first thickness of the second semiconductor material 430 satisfies a threshold (e.g., is too large), an etching procedure may be performed to reduce the thickness of the second semiconductor material 430.

After forming the second semiconductor material 430 along the sidewall of the cavities 425, the first semiconductor material 435 may be formed along a sidewall of the second semiconductor material 430, where the first semiconductor material 435 may have a second thickness. In such examples, if the second thickness of the first semiconductor material 435 satisfies a threshold (e.g., is too large), an etching procedure may be performed to reduce the thickness of the first semiconductor material 435. After forming the first semiconductor material 435, the second dielectric material 440 may be deposited into a remaining portion of the cavity 425, thereby forming the pillar 310.

FIG. 4F shows the architecture 400 (e.g., as an architecture 400-f) after a sixth set of one or more fabrication operations. The techniques described in the context of FIG. 4F may be used to reform the cavities 410-a and 410-b of the architecture 400. For example, in response to forming the pillar 310, the sacrificial material 415 may be exhumed, thereby reforming the cavities 410-a and 410-b. That is, the remaining portions of the sacrificial material 415 may be exhumed, which may reform the cavities 410-a and 410-b.

FIG. 4G shows the architecture 400 (e.g., as an architecture 400-g) after a seventh set of one or more fabrication operations. The techniques described in the context of FIG. 4G may be used to form the portions 305, the bit lines 155, and the dielectric pillars 315 of the architecture 400. For example, in response to reforming the cavities 410-a and 410-b, the dielectric pillars 315 may be formed.

To form the dielectric pillars 315, a first selective etch (e.g., lateral wet etch) may be performed through the cavity 410-a to etch through second semiconductor material 430 and through the first semiconductor material 435 to the pillar 310 (e.g., the second dielectric material 440) at a first side of the pillar 310 along the x-direction. Similarly, a second selective etch may be performed through the cavity 410-b to etch through the second semiconductor material 430 and through the first semiconductor material 435 to the pillar 310 (e.g., the second dielectric material 440) at a second side of the pillar 310 opposite the first side. By doing so, the portions 305 of the second semiconductor material 430 may be formed and the bit lines 155 may be formed.

In response, the dielectric pillar 315-a may be formed, such that the dielectric pillar 315-a is in contact with the pillar 310 and separates the portion 305-a and the bit line 155-a from the portion 305-b and the bit line 155-b at the first side of the pillar 310. For example, the first dielectric material 445 may be formed in the cavity 410-a and into the portions removed from the second semiconductor material 430 and the first semiconductor material 435 as a result of the first selective etch.

Similarly, the dielectric pillar 315-b may be formed, such that the dielectric pillar 315-b is in contact with the pillar 310 and separates the portion 305-a and the bit line 155-a from the portion 305-b and the bit line 155-b at the second side of the pillar 310. For example, the first dielectric material 445 may be formed in the cavity 410-b and into the portions removed from the second semiconductor material 430 and the first semiconductor material 435 as a result of the second selective etch.

FIG. 4H shows the architecture 400 (e.g., as an architecture 400-h) after an eighth set of one or more fabrication operations. The techniques described in the context of FIG. 4H may be used to form the word lines 165 of the architecture 400. For example, a metallization procedure (e.g., RG procedure) may be performed to replace the nitride layers 405 of the stack with metal (e.g., a conductive material), thereby forming multiple word lines 165. To do so, the nitride layers 405 may be removed (e.g., via an etching procedure), thereby forming multiple voids (e.g., one for each nitride layer 405). Accordingly, the metal may be deposited into each of the voids, thereby forming the word lines 165. In such examples, the metallization procedure may be performed through slits 450 positioned at one or more lateral edges of the architecture 400 along the x-direction or the y-direction. As an illustrative example, a slit 450-a may be positioned at a first lateral edge of the architecture 400 along the x-direction and a slit 450-b may be positioned at a second lateral edge of the architecture opposite the first lateral edge. In such examples, the metallization procedure may be performed through the slit 450-a, the slit 450-b, or both. Additionally, although not illustrated, the slits 450 may be positioned at a third lateral edge and a fourth lateral edge of the architecture 400 along the y-direction, which may be utilized to perform the metallization procedure.

FIGS. 4I and 4J may illustrate an alternative method to fabricate the architecture 400, where the one or more fabrication operations described in the FIGS. 4I and 4J may be performed in response to the sixth set of one or more fabrication operations, as described in FIG. 4F.

FIG. 4I shows the architecture 400 (e.g., as an architecture 400-i) after a seventh set of one or more fabrication operations. The techniques described in the context of FIG. 4I may be used to form the word lines 165 of the architecture 400. For example, in response to reforming the cavities 410-a and 410-b (e.g., via removal of the sacrificial material 415) a metallization procedure (e.g., RG procedure) may be performed to replace the nitride layers 405 of the stack with metal (e.g., a conductive material), thereby forming multiple word lines 165. To do so, the nitride layers 405 may be removed (e.g., via an etching procedure), thereby forming multiple voids (e.g., one for each nitride layer 405). Accordingly, the metal may be deposited into each of the voids, thereby forming the word lines 165. In such examples, the metallization procedure may be performed through the cavities 410-a and 410-b.

FIG. 4J shows the architecture 400 (e.g., as an architecture 400-j) after a tenth set of one or more fabrication operations. The techniques described in the context of FIG. 4J may be used to form the portions 305, the bit lines 155, and the dielectric pillars 315 of the architecture 400. For example, in response to forming the word lines 165, the dielectric pillars 315 may be formed.

To form the dielectric pillars 315, a first selective etch (e.g., lateral wet etch) may be performed through the cavity 410-a to etch through second semiconductor material 430 and through the first semiconductor material 435 to the pillar 310 (e.g., the second dielectric material 440) at a first side of the pillar 310 along the x-direction. Similarly, a second selective etch may be performed through the cavity 410-b to etch through the second semiconductor material 430 and through the first semiconductor material 435 to the pillar 310 (e.g., the second dielectric material 440) at a second side of the pillar 310 opposite the first side. By doing so, the portions 305 of the second semiconductor material 430 may be formed and the bit lines 155 may be formed.

In response, the dielectric pillar 315-a may be formed, such that the dielectric pillar 315-a is in contact with the pillar 310 and separates the portion 305-a and the bit line 155-a from the portion 305-b and the bit line 155-b at the first side of the pillar 310. For example, the first dielectric material 445 may be formed in the cavity 410-a and into the portions removed from the second semiconductor material 430 and the first semiconductor material 435 as a result of the first selective etch.

Similarly, the dielectric pillar 315-b may be formed, such that the dielectric pillar 315-b is in contact with the pillar 310 and separates the portion 305-a and the bit line 155-a from the portion 305-b and the bit line 155-b at the second side of the pillar 310. For example, the first dielectric material 445 may be formed in the cavity 410-b and into the portions removed from the second semiconductor material 430 and the first semiconductor material 435 as a result of the second selective etch.

FIG. 4K shows the architecture 400 (e.g., as an architecture 400-K) after an eighth set of one or more fabrication operations. The techniques described in the context of FIG. 4K may be performed in response to the fabrication operations of FIG. 4G. For example, a metallization procedure (e.g., RG procedure) may be performed to replace the nitride layers 405 of the stack with metal (e.g., a conductive material), thereby forming multiple word lines 165. To do so, the nitride layers 405 may be removed (e.g., via an etching procedure), thereby forming multiple voids (e.g., one for each nitride layer 405). Accordingly, the metal may be deposited into each of the voids, thereby forming the word lines 165.

In such examples, the metallization procedure may be performed through slits 450 positioned at one or more lateral edges of the architecture 400 along the x-direction or the y-direction. As an illustrative example, a slit 450-c may be positioned at a first lateral edge of the architecture 400 along the x-direction and a slit 450-d may be positioned at a second lateral edge of the architecture opposite the first lateral edge. In such examples, the metallization procedure may be performed through the slit 450-c, the slit 450-d, or both. Additionally, although not illustrated, the slits 450 may be positioned at a third lateral edge and a fourth lateral edge of the architecture 400 along the y-direction, which may be utilized to perform the metallization procedure.

Further, the slits 450-c and 450-d may be formed on the architecture 400 to maintain increased symmetry on the block (e.g., the architecture 400) and to leave a defined margin (e.g., distance from the first active cells) for the metal recess from the slits 450, thereby enabling the formation and separation of the word lines 165. In this way, a distance 455 between the slits 450 and the portions 305 (e.g., the active cells) may be uniform.

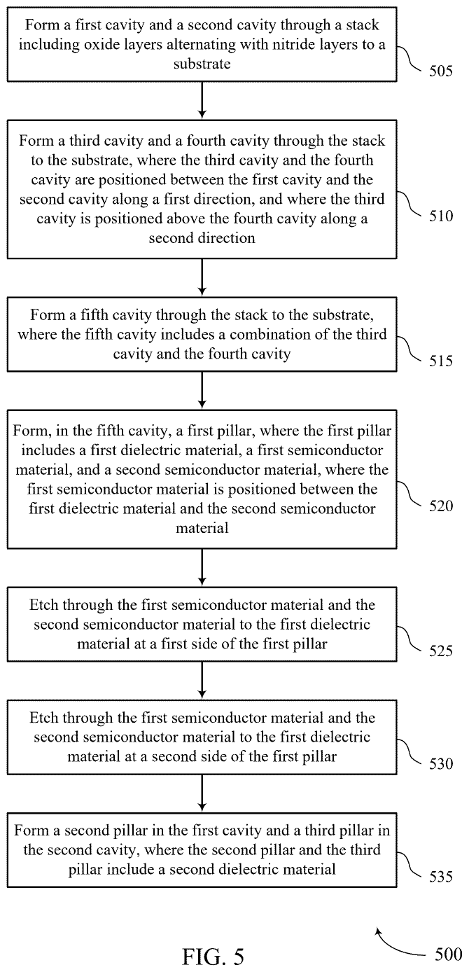

FIG. 5 shows a flowchart illustrating a method 500 that supports split pillar memory architectures in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include forming a first cavity and a second cavity through a stack including oxide layers alternating with nitride layers to a substrate.

At 510, the method may include forming a third cavity and a fourth cavity through the stack to the substrate, where the third cavity and the fourth cavity are positioned between the first cavity and the second cavity along a first direction, and where the third cavity is positioned above the fourth cavity along a second direction.

At 515, the method may include forming a fifth cavity through the stack to the substrate, where the fifth cavity includes a combination of the third cavity and the fourth cavity.

At 520, the method may include forming, in the fifth cavity, a first pillar, where the first pillar includes a first dielectric material, a first semiconductor material, and a second semiconductor material, where the first semiconductor material is positioned between the first dielectric material and the second semiconductor material.

At 525, the method may include etching through the first semiconductor material and the second semiconductor material to the first dielectric material at a first side of the first pillar.

At 530, the method may include etching through the first semiconductor material and the second semiconductor material to the first dielectric material at a second side of the first pillar.

At 535, the method may include forming a second pillar in the first cavity and a third pillar in the second cavity, where the second pillar and the third pillar include a second dielectric material.

In some examples, an apparatus (e.g., a manufacturing system) as described herein may perform a method or methods, such as the method 500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure

Aspect 1: A method or apparatus including operations, features, circuitry, logic, means, or instructions, or any combination thereof for forming a first cavity and a second cavity through a stack including oxide layers alternating with nitride layers to a substrate; forming a third cavity and a fourth cavity through the stack to the substrate, where the third cavity and the fourth cavity are positioned between the first cavity and the second cavity along a first direction, and where the third cavity is positioned above the fourth cavity along a second direction; forming a fifth cavity through the stack to the substrate, where the fifth cavity includes a combination of the third cavity and the fourth cavity; forming, in the fifth cavity, a first pillar, where the first pillar includes a first dielectric material, a first semiconductor material, and a second semiconductor material, where the first semiconductor material is positioned between the first dielectric material and the second semiconductor material; etching through the first semiconductor material and the second semiconductor material to the first dielectric material at a first side of the first pillar; etching through the first semiconductor material and the second semiconductor material to the first dielectric material at a second side of the first pillar; and forming a second pillar in the first cavity and a third pillar in the second cavity, where the second pillar and the third pillar include a second dielectric material.

Aspect 2: The method or apparatus of aspect 1, further including operations, features, circuitry, logic, means, or instructions, or any combination thereof for forming a plurality of word lines in place of the nitride layers of the stack, where the plurality of word lines are formed in accordance with forming the first pillar, where the plurality of word lines are formed through the first cavity and the second cavity.

Aspect 3: The method or apparatus of any of aspects 1 through 2, further including operations, features, circuitry, logic, means, or instructions, or any combination thereof for forming a plurality of word lines in place of the nitride layers of the stack, where the plurality of word lines are formed in accordance with forming the second pillar and the third pillar, and where the plurality of word lines are formed through a slit positioned at a lateral edge of the memory device.

Aspect 4: The method or apparatus of any of aspects 1 through 3, further including operations, features, circuitry, logic, means, or instructions, or any combination thereof for forming a first portion of a sacrificial material in the first cavity; forming a second portion of the sacrificial material in the second cavity; forming a third portion of the sacrificial material in the third cavity; and forming a fourth portion of the sacrificial material in the fourth cavity, where forming the fifth cavity is in accordance with forming the sacrificial material.

Aspect 5: The method or apparatus of aspect 4, further including operations, features, circuitry, logic, means, or instructions, or any combination thereof for masking the first portion and the second portion of the sacrificial material in accordance with forming the sacrificial material and exhuming the third portion and the fourth portion of the sacrificial material to reform the third cavity and the fourth cavity in accordance with masking the first portion and the second portion of the sacrificial material, where forming the fifth cavity is in accordance with exhuming the third portion and the fourth portion of the sacrificial material.

Aspect 6: The method or apparatus of any of aspects 4 through 5, further including operations, features, circuitry, logic, means, or instructions, or any combination thereof for exhuming the first portion and the second portion of the sacrificial material to reform the first cavity and the second cavity, where etching through the first semiconductor material and the second semiconductor material is in accordance with exhuming the first portion and the second portion of the sacrificial material.

Aspect 7: The method or apparatus of any of aspects 1 through 6, where forming the fifth cavity includes operations, features, circuitry, logic, means, or instructions, or any combination thereof for removing a portion of the stack between the third cavity and the fourth cavity to enlarge the third cavity and the fourth cavity.

Aspect 8: The method or apparatus of aspect 7, where enlarging the third cavity and the fourth cavity to form the fifth cavity includes operations, features, circuitry, logic, means, or instructions, or any combination thereof for selectively etching material surrounding the third cavity, and selectively etching material surrounding the fourth cavity, wherein the fifth cavity is formed according to selectively etching the material surrounding the third cavity and selectively etching the material surrounding the fourth cavity.

Aspect 9: The method or apparatus of any of aspects 1 through 8, where forming the first pillar includes operations, features, circuitry, logic, means, or instructions, or any combination thereof for forming the second semiconductor material along a sidewall of the fifth cavity; forming the first semiconductor material along a sidewall of the second semiconductor material; and forming the first dielectric material in a remaining portion of the fifth cavity.

Aspect 10: The method or apparatus of any of aspects 1 through 9, where forming the first pillar includes operations, features, circuitry, logic, means, or instructions, or any combination thereof for forming the second semiconductor material in the fifth cavity; forming a sixth cavity through the second semiconductor material; forming the first semiconductor material in the fourth cavity; forming a seventh cavity through the first semiconductor material; and forming the first dielectric material in the seventh cavity.

Aspect 11: The method or apparatus of any of aspects 1 through 10, where etching through the first semiconductor material at the first side and the second side of the first pillar separates the first semiconductor material into a first portion of the first semiconductor material at a third side of the first pillar and a second portion of the first semiconductor material at a fourth side of the first pillar opposite the second side.

Aspect 12: The method or apparatus of any of aspects 1 through 11, where etching through the second semiconductor material at the first side and the second side of the first pillar separates the second semiconductor material into a first portion of the second semiconductor material at a third side of the first pillar and a second portion of the second semiconductor material at a fourth side of the first pillar opposite the second side.

Aspect 13: The method or apparatus of any of aspects 1 through 12, where the first cavity, the second cavity, the third cavity, and the fourth cavity are formed at a same time.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 14: A memory device, including: a first pillar including a first dielectric material; a second pillar including the first dielectric material; a third pillar positioned between the first pillar and the second pillar, the third pillar including a second dielectric material; a first portion of a first semiconductor material along a first side of the third pillar; a second portion of the first semiconductor material along a second side of the third pillar opposite the first side; a first portion of a second semiconductor material positioned between a plurality of word lines and the first portion of the first semiconductor material; and a second portion of the second semiconductor material positioned between the plurality of word lines and the second portion of the first semiconductor material.

Aspect 15: The memory device of aspect 14, further including: a plurality of oxide layers, where each oxide layer of the plurality of oxide layers is positioned between a respective first word line of the plurality of word lines and a respective second word line of the plurality of word lines.

Aspect 16: The memory device of any of aspects 14 through 15, further including: a fourth pillar including the first dielectric material; a fifth pillar positioned between the second pillar and the fourth pillar, the fifth pillar including the second dielectric material; a third portion of the first semiconductor material along a first side of the fifth pillar; a fourth portion of the first semiconductor material along a second side of the fifth pillar opposite the first side; a third portion of the second semiconductor material positioned between the plurality of word lines and the third portion of the first semiconductor material; and a fourth portion of the second semiconductor material positioned between the plurality of word lines and the fourth portion of the first semiconductor material.

Aspect 17: The memory device of any of aspects 14 through 16, where the first portion of the first semiconductor material and the first portion of the second semiconductor material have one of a hemicylindrical form, a semielliptical form, a rounded rectangular form, or a combination thereof, and the second portion of the first semiconductor material and the second portion of the second semiconductor material have one of the hemicylindrical form, the semielliptical form, the rounded rectangular form, or a combination thereof.

Aspect 18: The memory device of any of aspects 14 through 17, where the first portion of the second semiconductor material forms a plurality of first memory cells at the first side of the third pillar, and the second portion of the second semiconductor material forms a plurality of second memory cells at the second side of the third pillar.

Aspect 19: The memory device of any of aspects 14 through 18, where the first portion of the first semiconductor material extends along a length of the first side of the first pillar, and the second portion of the first semiconductor material extends along a length of the second side of the first pillar.

Aspect 20: The memory device of any of aspects 14 through 19, where the first portion of the second semiconductor material extends along a length of the first portion of the first semiconductor material, and the second portion of the second semiconductor material extends along a length of the second portion of the first semiconductor material.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a first pillar comprising a first dielectric material;
a second pillar comprising the first dielectric material;
a third pillar positioned between the first pillar and the second pillar, the third pillar comprising a second dielectric material;
a first portion of a first semiconductor material along a first side of the third pillar;
a second portion of the first semiconductor material along a second side of the third pillar opposite the first side;
a first portion of a second semiconductor material positioned between a plurality of word lines and the first portion of the first semiconductor material; and
a second portion of the second semiconductor material positioned between the plurality of word lines and the second portion of the first semiconductor material.

2. The memory device of claim 1, further comprising:
a plurality of oxide layers, wherein each oxide layer of the plurality of oxide layers is positioned between a respective first word line of the plurality of word lines and a respective second word line of the plurality of word lines.

3. The memory device of claim 1, further comprising:
a fourth pillar comprising the first dielectric material;
a fifth pillar positioned between the second pillar and the fourth pillar, the fifth pillar comprising the second dielectric material;
a third portion of the first semiconductor material along a first side of the fifth pillar;
a fourth portion of the first semiconductor material along a second side of the fifth pillar opposite the first side;
a third portion of the second semiconductor material positioned between the plurality of word lines and the third portion of the first semiconductor material; and
a fourth portion of the second semiconductor material positioned between the plurality of word lines and the fourth portion of the first semiconductor material.

4. The memory device of claim 1, wherein:
the first portion of the first semiconductor material and the first portion of the second semiconductor material have one of a hemicylindrical form, a semielliptical form, a rounded rectangular form, or a combination thereof, and
the second portion of the first semiconductor material and the second portion of the second semiconductor material have one of the hemicylindrical form, the semielliptical form, the rounded rectangular form, or a combination thereof.

5. The memory device of claim 1, wherein:
the first portion of the second semiconductor material forms a plurality of first memory cells at the first side of the third pillar, and
the second portion of the second semiconductor material forms a plurality of second memory cells at the second side of the third pillar.

6. The memory device of claim 1, wherein:
the first portion of the first semiconductor material extends along a length of the first side of the first pillar, and
the second portion of the first semiconductor material extends along a length of the second side of the first pillar.

7. The memory device of claim 1, wherein:
the first portion of the second semiconductor material extends along a length of the first portion of the first semiconductor material, and
the second portion of the second semiconductor material extends along a length of the second portion of the first semiconductor material.

8. A method for manufacturing a memory device, comprising:
forming a first cavity and a second cavity through a stack comprising oxide layers alternating with nitride layers to a substrate;
forming a third cavity and a fourth cavity through the stack to the substrate, wherein the third cavity and the fourth cavity are positioned between the first cavity and the second cavity along a first direction, and wherein the third cavity is positioned above the fourth cavity along a second direction;
forming a fifth cavity through the stack to the substrate, wherein the fifth cavity comprises a combination of the third cavity and the fourth cavity;
forming, in the fifth cavity, a first pillar, wherein the first pillar comprises a first dielectric material, a first semiconductor material, and a second semiconductor material, wherein the first semiconductor material is positioned between the first dielectric material and the second semiconductor material;
etching through the first semiconductor material and the second semiconductor material to the first dielectric material at a first side of the first pillar;
etching through the first semiconductor material and the second semiconductor material to the first dielectric material at a second side of the first pillar; and
forming a second pillar in the first cavity and a third pillar in the second cavity, wherein the second pillar and the third pillar comprise a second dielectric material.

9. The method of claim 8, further comprising:
forming a plurality of word lines in place of the nitride layers of the stack, wherein the plurality of word lines are formed in accordance with forming the first pillar, wherein the plurality of word lines are formed through the first cavity and the second cavity.

10. The method of claim 8, further comprising:
forming a plurality of word lines in place of the nitride layers of the stack, wherein the plurality of word lines are formed in accordance with forming the second pillar and the third pillar, and wherein the plurality of word lines are formed through a slit positioned at a lateral edge of the memory device.

11. The method of claim 8, further comprising:
forming a first portion of a sacrificial material in the first cavity;
forming a second portion of the sacrificial material in the second cavity;
forming a third portion of the sacrificial material in the third cavity; and
forming a fourth portion of the sacrificial material in the fourth cavity, wherein forming the fifth cavity is in accordance with forming the sacrificial material.

12. The method of claim 11, further comprising:
masking the first portion and the second portion of the sacrificial material in accordance with forming the sacrificial material; and
exhuming the third portion and the fourth portion of the sacrificial material to reform the third cavity and the fourth cavity in accordance with masking the first portion and the second portion of the sacrificial material, wherein forming the fifth cavity is in accordance with exhuming the third portion and the fourth portion of the sacrificial material.

13. The method of claim 11, further comprising:
exhuming the first portion and the second portion of the sacrificial material to reform the first cavity and the second cavity, wherein etching through the first semiconductor material and the second semiconductor material is in accordance with exhuming the first portion and the second portion of the sacrificial material.

14. The method of claim 8, wherein forming the fifth cavity comprises:
removing a portion of the stack between the third cavity and the fourth cavity to enlarge the third cavity and the fourth cavity.

15. The method of claim 14, wherein the enlargement of the third cavity and the fourth cavity to form the fifth cavity comprises:
selectively etching material surrounding the third cavity; and
selectively etching material surrounding the fourth cavity, wherein the fifth cavity is formed according to selectively etching the material surrounding the third cavity and selectively etching the material surrounding the fourth cavity.

16. The method of claim 8, wherein forming the first pillar comprises:
forming the second semiconductor material along a sidewall of the fifth cavity;
forming the first semiconductor material along a sidewall of the second semiconductor material; and
forming the first dielectric material in a remaining portion of the fifth cavity.

17. The method of claim 8, wherein forming the first pillar comprises:
forming the second semiconductor material in the fifth cavity;
forming a sixth cavity through the second semiconductor material;
forming the first semiconductor material in the fourth cavity;
forming a seventh cavity through the first semiconductor material; and
forming the first dielectric material in the seventh cavity.

18. The method of claim 8, wherein etching through the first semiconductor material at the first side and the second side of the first pillar separates the first semiconductor material into a first portion of the first semiconductor material at a third side of the first pillar and a second portion of the first semiconductor material at a fourth side of the first pillar opposite the second side.

19. The method of claim 8, wherein etching through the second semiconductor material at the first side and the second side of the first pillar separates the second semiconductor material into a first portion of the second semiconductor material at a third side of the first pillar and a second portion of the second semiconductor material at a fourth side of the first pillar opposite the second side.

20. A memory device formed by a process, comprising:
forming a first cavity and a second cavity through a stack comprising oxide layers alternating with nitride layers to a substrate;
forming a third cavity and a fourth cavity through the stack to the substrate, wherein the third cavity and the fourth cavity are positioned between the first cavity and the second cavity along a first direction, and wherein the third cavity is positioned above the fourth cavity along a second direction;
forming a fifth cavity through the stack to the substrate, wherein the fifth cavity comprises a combination of the third cavity and the fourth cavity;
forming, in the fifth cavity, a first pillar, wherein the first pillar comprises a first dielectric material, a first semiconductor material, and a second semiconductor material, wherein the first semiconductor material is positioned between the first dielectric material and the second semiconductor material;
etching through the first semiconductor material and the second semiconductor material to the first dielectric material at a first side of the first pillar;
etching through the first semiconductor material and the second semiconductor material to the first dielectric material at a second side of the first pillar; and
forming a second pillar in the first cavity and a third pillar in the second cavity, wherein the second pillar and the third pillar comprise a second dielectric material.
